(19) United States
(12) Patent Application Publication
(10) Pub. No.: US 2005/0093577 A1
(43) Pub. Date: May 5, 2005

(54) Multiplexer circuits

(76) Inventors: Liem Nguyen, Austin, TX (US); Xiaojie He, Austin, TX (US); Brian Gaide, Austin, TX (US); Kerry Ilgenstein, Austin, TX (US); Sajitha Wijesuriya, Macungie, PA (US); Claudia Stanley, Austin, TX (US); Aaron Rogers, Austin, TX (US); Zheng Chen, Macungie, PA (US)

Correspondence Address: Greg J, Michelson;MacPHERSON KWOK CHEN & HEID LLP, Suite 226, 1762 Technology Drive, San Jose, CA, 95110, US

(21) Appl. No.: 10/701,667

(22) Filed: Nov. 4, 2003

(51) Int. Cl. H03K 19/094

(52) U.S. Cl. 326/105

(57) ABSTRACT

Multiplexer circuits are disclosed, such as for example for programmable logic devices. As an example of one embodiment, a multiplexer circuit is disclosed having a default state and a state-locking latch.

### TECHNICAL FIELD

The present invention relates generally to electrical circuits and, more particularly, to multiplexer circuits.

### BACKGROUND

Programmable logic devices are well known and are employed in a variety of applications. A typical programmable logic device (PLD), such as for example a field programmable gate array (FPGA), may include a core having repetitive blocks of logic that interface with each other through an interconnect architecture.

The interconnect architecture may include metal wires and multiplexers, which together are known as or may be referred to as the “routing” or the “interconnect” of the PLD. The multiplexers function as the routing-steering circuits for signals carried by the interconnect and are generally controlled or set via software. For example, the software may select a specific routing path out of many possible paths associated with a particular multiplexer (also referred to as a mux), based on a user's design or desired logic implementation, to form an interconnect connection between two blocks of logic.

In general, PLD performance often depends significantly on the interconnect architecture, with the multiplexers typically being a critical component and consuming a major portion of the PLD's total power. As an example, FIG. 1 shows a circuit diagram illustrating a typical conventional multiplexer 100. Conventional multiplexers, such as multiplexer 100, may have a number of drawbacks or performance limitations, as explained further herein. For example, conventional multiplexers have a significant amount of leakage current, introduce additional propagation delays, limit routing resources due to tie-down requirements, and/or cause power spikes during configuration or reconfiguration. As a result, there is a need for improved multiplexer circuits.

### SUMMARY

Systems and methods are disclosed herein to provide multiplexer circuits, such as for programmable logic devices or other types of integrated circuits. For example, in accordance with an embodiment of the present invention, a multiplexer circuit is disclosed having a default state and/or a state-locking latch. The multiplexer circuit may provide certain improvements and advantages over conventional multiplexer circuits.

More specifically, in accordance with one embodiment of the present invention, a multiplexer includes a plurality of first transistors adapted to receive a plurality of input signals, wherein the plurality of first transistors provides at least two first-stage multiplexer output signals; a plurality of second transistors adapted to receive the first-stage multiplexer output signals and provide a second-stage multiplexer output signal; a first inverter adapted to receive the second-stage multiplexer output signal at an input terminal and provide an output signal at an output terminal; a third transistor, coupled to the input terminal of the first inverter, adapted to pull a voltage level at the input terminal to a rail voltage; and a fourth transistor, coupled to the input terminal and the output terminal of the first inverter.

In accordance with another embodiment of the present invention, a programmable logic device includes a plurality of multiplexers, with each multiplexer of the plurality having a plurality of first transistors adapted to receive input signals and provide a multiplexed output signal; a first inverter having an input terminal and an output terminal, the first inverter adapted to receive the multiplexed output signal at the input terminal and provide an inverted output signal at the output terminal; a second and a third transistor coupled to the input terminal and the output terminal of the first inverter, which form a full latch; and a fourth transistor, coupled to the input terminal of the first inverter, adapted to receive a control signal and pull a voltage level at the input terminal to a rail voltage when the control signal is asserted.

In accordance with another embodiment of the present invention, a method of operating a multiplexer within a programmable logic device includes providing a first control signal to the multiplexer to set an output signal of the multiplexer to a default state; maintaining the default state of the output signal of the multiplexer; and providing at least a second control signal to determine which if any of a plurality of input signals to select and provide as the output signal of the multiplexer.

In accordance with another embodiment of the present invention, a multiplexer includes a plurality of first transistors adapted to receive a plurality of input signals, wherein the plurality of first transistors provides a multiplexer output signal; an inverter adapted to receive the multiplexer output signal at an input terminal and provide an output signal at an output terminal; a second transistor, coupled to the input terminal of the inverter, adapted to pull a voltage level at the input terminal to a rail voltage; and a third transistor, coupled to the input terminal and the output terminal of the inverter, adapted to maintain a voltage level at the input terminal at the rail voltage based upon a voltage level of the output signal at the output terminal.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 shows a circuit diagram illustrating a conventional multiplexer.

FIG. 2 shows a circuit diagram illustrating a multiplexer in accordance with an embodiment of the present invention.

FIG. 3 shows a circuit diagram illustrating a multiplexer in accordance with an embodiment of the present invention.

Embodiments of the present invention and their advantages are best understood by referring to the detailed description that follows. It should be appreciated that like reference numerals are used to identify like elements illustrated in one or more of the figures.

### DETAILED DESCRIPTION

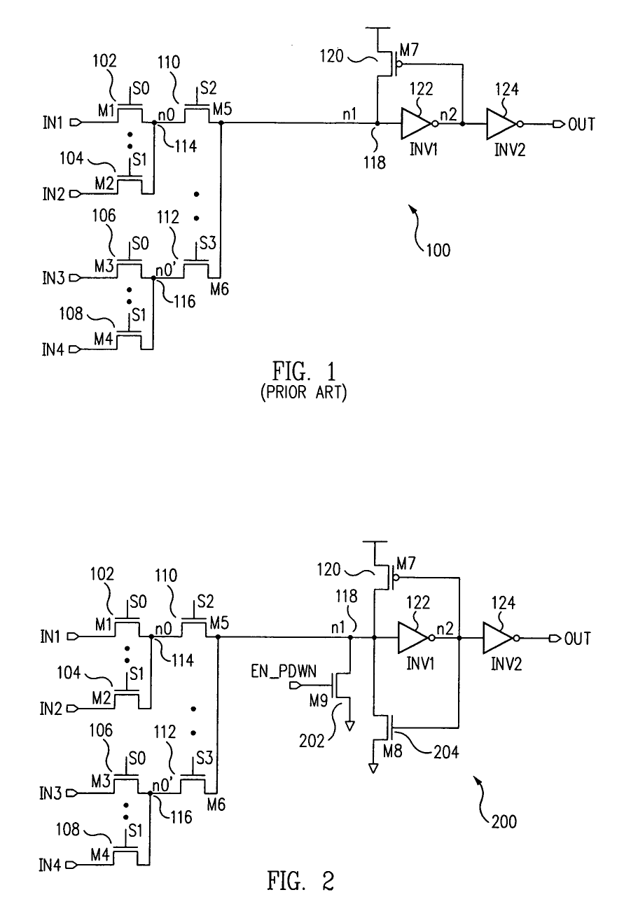

FIG. 2 shows a circuit diagram illustrating a multiplexer 200 in accordance with an embodiment of the present invention. Multiplexer 200 may be included as one of many similar multiplexers within an integrated circuit. For example, a programmable logic device, such as a field programmable gate array (FPGA), a complex programmable logic device (CPLD), or a programmable interconnect, may include a number of multiplexers 200.

Multiplexer 200 includes transistors 102 through 112, 120, 202, and 204 (e.g., N or P channel metal oxide semiconductor transistors) and inverters 122 and 124 (e.g., driver inverters). Multiplexer 200 receives a number of input signals (e.g., labeled IN1 through IN4) and provides an output signal (labeled OUT). The input signals are multiplexer input signals that, for example, may originate from routing resources. The output signal is provided at an output port (e.g., a terminal or a lead) of multiplexer 200.

Transistors 102 and 104 form a first-stage multiplexer, transistors 106 and 108 form another first-stage multiplexer, and transistors 110 and 112 form a second-stage multiplexer of multiplexer 200. It should be noted that the size of multiplexer 200 may vary depending upon the desired application or implementation requirements (e.g., the techniques and embodiments discussed herein are not limited to 4:1 multiplexers). For example, the number of input signals into each first-stage multiplexer, the number of first-stage multiplexers, and the number of input signals into the second-stage multiplexer (along with the number of transistors that form the first-stage and the second-stage) may vary. Also, for example, there may be additional stages (e.g., the addition of a third or fourth-stage).

Control signals (labeled S0, S1, S2, and S3), which may be provided by configuration memory cells (e.g., fuses or static random access memory cells), control transistors 102 through 112 as shown in FIG. 2. For example, the control signal S0 controls transistors 102 and 106, the control signal S1 controls transistors 104 and 108, the control signal S2 controls transistor 110, and the control signal S3 controls transistor 112.

In general, the two-stage multiplexing technique, illustrated by multiplexer 200, requires more pass gate transistors (e.g., transistors 102 through 112) but fewer control signals (e.g., the control signals S0-S3) than its one-stage equivalent. Thus, for example, if configuration memory cells are providing the control signals, then fewer configuration memory cells are required for a two-stage multiplexer than for its one-stage equivalent.

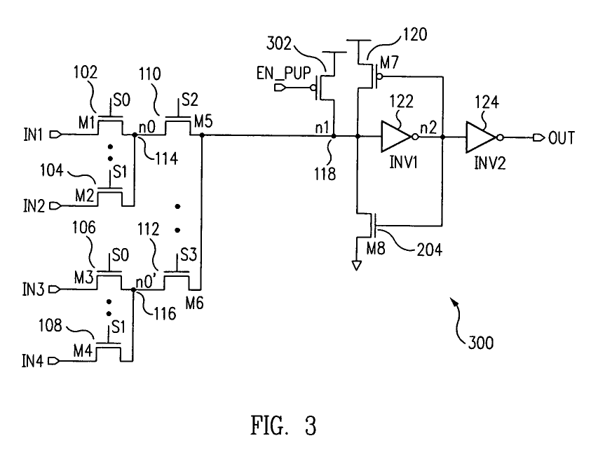

Transistor 202 functions as a pull-down transistor to pull the voltage level at a node 118 (labeled n1) to ground when a pull-down control signal (labeled EN_PDWN) is asserted. The pull-down control signal, for example, may be a pulse (e.g., a global pulse) asserted during power-up and/or device initialization. Alternatively, referring briefly to FIG. 3, transistor 302 may function as a pull-up transistor to pull a voltage level at node 118 to a supply voltage level (e.g., VCC) when a pull-up control signal (e.g., a global pulse and labeled EN_PUP, which may be the complement of the control signal EN_PDWN) is asserted (e.g., at power-up and/or device initialization), as illustrated by transistor 302 of multiplexer 300 of FIG. 3 in accordance with an embodiment of the present invention. However, overall leakage currents may be less for multiplexer 200 with the pull-down transistor 202 as compared to multiplexer 300 with the pull-up transistor 302, depending upon the application and device architecture.

Transistors 120 and 204 along with inverter 122 function as a full latch to maintain a voltage level at node 118 at the supply voltage level or ground, depending upon a signal provided by inverter 122. Inverter 124 provides the output signal (OUT) for multiplexer 200. In accordance with one or more embodiments of the present invention, multiplexer 200 may be implemented without transistor 120 or transistor 204. Similarly, multiplexer 200 and multiplexer 300 may be implemented without transistor 202 or transistor 302.

As explained herein, conventional multiplexer circuits may have certain drawbacks or performance limitations. For example, these drawbacks or limitations may include direct current (DC) leakage currents and propagation delays associated with the use of a multiplexer input path as a default-state input path in unused multiplexers, problems with software tie-downs and/or limited routing resources (which may also be associated with the use of default-state input paths in unused multiplexers), and power spikes during reconfiguration due to the multiplexer being in an unknown state. Note that an unused multiplexer, in general, is a multiplexer that does not pass active signals from its input to output terminal.

For example, referring to FIG. 1, without a method to control a default state of multiplexer 100, a voltage level at node 118 may float (if multiplexer 100 is an unused multiplexer) and cause crowbar current (e.g., a current flow induced due to an asserted voltage level being between a supply voltage and a ground voltage level) to flow through inverters 122 and/or 124. As an example, conventional techniques employ a multiplexer input (e.g., a path through transistors 102 and 110 for the input signal IN1 of multiplexer 100) as a default-state input path to connect node 118 to a supply voltage or to ground via the input signal IN1. However, even though the default-state input path helps to alleviate the problem of node 118 floating, undesirable DC leakage currents and propagation delays may be created.

For example, the two-stage multiplexer scheme of multiplexer 100 may reduce the number of configuration memory cells (e.g., required to provide control signals) and thus, the area used by the configuration memory cells. Consequently, the same configuration memory cell signal such as the control signal S0 controls transistors 102 and 106 and likewise the same configuration memory cell that provides control signal S1 controls transistors 104 and 108. This dual control of the configuration memory cells contributes to a phenomenon referred to as “pseudo loading.”

In general, although only one of the input signals propagates through multiplexer 100 as the output signal (i.e., due to only transistor 110 or transistor 112 switched on), the fact that several first-stage multiplexer transistors (i.e., from among transistors 102 through 108) are simultaneously switched on, by the corresponding shared control signal, may increase DC leakage currents within multiplexer 100 by creating leakage paths when the input signals are in opposite states. These leakage currents may represent a significant portion of the overall consumed power in integrated circuits manufactured with leading-edge technologies. Furthermore, propagation delays may also increase due to the added capacitance seen by the other input signals through these switched on transistors.

As an example, assume multiplexer 100 is unused and is set to a default state with the input signal IN1 selected as the default signal and providing a stable high or low logical signal level (i.e., transistors 102 and 110 provide the default-state input path). The control signals S0 and S2 are asserted, which switches on transistors 102 and 110 but also transistor 106. The input signal (IN3) may be assumed to be a signal from another multiplexer within the integrated circuit (i.e., another driving multiplexer such as multiplexer 100) and that the input signal (IN3) is also being provided to other multiplexers. This assumption is reasonable considering that routing signals may have a large fan-out (i.e., a large number of output signal paths).

Therefore, although multiplexer 100 does not use the input signal (IN3) because multiplexer 100 is unused, transistor 106 will be switched on due to the assertion of the control signal S0 being asserted to form the default-state input path through transistor 102. Consequently, the input signal (IN3) may see a parasitic capacitive load at a node 116, with this extra loading possibly increasing propagation delays and also increasing alternating current (AC) power consumption.

Furthermore, leakage currents may increase in the unused multiplexers due to the “pseudo loading” effect. For example, assume the input signal (IN3) is asserted or in transition (e.g., switching from a logical high/low to a logical low/high) and the input signal (IN4) and node 118 are at a logical low voltage level. Both signal paths within multiplexer 100 for the input signal (IN3) have two series transistors (i.e., the input signal (IN3) may pass through transistors 106 and 108 or through transistors 106 and 112). Therefore, if one of the transistors is switched on (e.g., transistor 106), then associated leakage currents may be much higher through these signal paths than if the transistors (e.g., transistors 106 and 108 or transistors 106 and 112) were switched off.

In contrast, in accordance with an embodiment of the present invention, rather than using a dedicated input path (or signal path) as a default-state input path to set an unused routing multiplexer (e.g., multiplexer 200) to a known state, transistors 102 through 112 are switched off to deny any of the input signals (e.g., IN1 through IN4) from reaching node 118 (FIG. 2). Node 118 is pulled to ground by pull-down transistor 202 and is kept at a logical low level by transistor 204 (a latch feedback transistor). Alternatively, node 118 is pulled to a supply voltage level by pull-up transistor 302 (multiplexer 300 of FIG. 3) and is kept at a logical high level by transistor 120.

As explained above, the control signal (EN_PDWN of multiplexer 200 of FIG. 2) and the control signal (EN_PUP of multiplexer 300 of FIG. 3) function as a pull-down signal and a pull-up signal, respectively, and each may be a pulse asserted during power-up and/or full configuration. Node 118, after assertion of the control signal (EN_PDWN or EN_PUP), remains at its voltage level state (e.g., at one of the rail voltages) due to the full-latch function of transistors 120 and 204. If the control signal (EN_PDWN or EN_PUP) were not a pulse and asserted during normal integrated circuit operation (e.g., a user mode of a programmable logic device), the multiplexers that were in use (i.e., not designated as unused multiplexers) may function poorly or not at all.

Multiplexers 200 and 300 may function to effectively eliminate the pseudo-loading limitations of unused multiplexers by switching off transistors 102 through 112 (i.e., the input signal routing transistors). The capacitance at node 116 is no longer seen by the input signal (IN3), as discussed in a previous example, and the leakage currents may be greatly reduced because there are two series transistors (e.g., pass gates such as transistors 106 and 112) switched off in each of the leakage paths.

Furthermore, for example, overall power requirements of an integrated circuit with multiplexers 200 may drop significantly as compared to a similar integrated circuit with conventional multiplexers. This may be due to the power saving pull-down/latch technique of multiplexer 200 when a number of the multiplexers are not used. For example, a majority of multiplexers 200 in the integrated circuit may be in a default state.

Although transistor 204 (of the full-latch) may resist the low-to-high transition of multiplexer 200, the added delay due to transistor 204 may be less than the delay decrease resulting from the elimination of the parasitic capacitance at node 116 and/or node 114 (depending upon the application and example). Transistor 204 may be sized very small compared to inverter drivers (e.g., from multiplexers providing the input signals, such as ones similar to inverters 122 and 124) to minimize this effect.

As mentioned herein as a drawback of conventional multiplexer techniques, default-state input paths may be set to a known state, for example, either through a dedicated hard-wired ground or supply signal or through a software tie-down (as explained further below). In addition to the problem from pseudo-loading, this conventional approach may reduce the routing resources and increase the software complexity. For example, when a particular multiplexer (e.g., one of multiplexers 100 within a programmable logic device) is not used by the software (i.e., data is not passed through that particular multiplexer), the multiplexer must still be forced to some default state. If not, node 118 (FIG. 1) could float at a non-rail voltage (e.g., at a voltage level between a supply voltage level and a reference voltage level), which may increase DC power consumption of the programmable logic device.

A conventional multiplexer technique, as discussed herein, requires an input path (e.g., via transistor 102, 104, 106, or 108) of multiplexer 100, referred to as the default-state input path, to connect node 118 to a supply voltage signal or a ground signal (i.e., a rail signal, where ground may represent zero volts or some other reference voltage) to prevent node 118 from floating. Typically, one multiplexer input via transistor 102, 104, 106, or 108 is connected directly to a rail. This technique reduces the routing richness because the hard-tied input path could otherwise be used as a signal routing path.

Another conventional multiplexer technique of creating a default-state input path is by selecting a multiplexer signal input path with a known state (as opposed to a simple tie or connection to a rail voltage), referred to as a software “tie-down.” In order to provide a tie-down, the software must be able to find, to one of the multiplexer's input paths, a signal path that is not used by any other multiplexer and then disallow that signal path to carry data. Depending on the design requirements, there may or may not be enough internal unused routing signals within the programmable logic device to satisfy this requirement. Even if there are enough unused signals available, routing resources once again become limited and software routing complexity increases.

It may also be difficult to assure that all of these unused routes have the same logic state. Often a design implementation will be limited to using default-high signals for some default-input input paths and using default-low signals for other default-state input paths. A mixture of default states leads to more current leakage paths than a singular default state due, in general, to more pass gates (transistors) having potential voltage drops across them.

In contrast, in accordance with an embodiment of the present invention, by employing the default-setting transistor 202 in multiplexer 200, the requirement of a default-state input path is eliminated, which then allows (or frees up) one more multiplexer path for signal routing. Software may also be simplified because it no longer has to determine which unused signals will become default-state paths.

As mentioned above, another potential drawback of conventional multiplexers is the possibility of power spikes during reconfiguration. For example, assume that multiplexer 100 is controlled to initially select the input signal (IN1) as its input signal. During reconfiguration, multiplexer 100 is controlled to select the input signal (IN4) as the input signal instead (based on a user's design or implementation). The control signals S0 and S2 must be deasserted (to switch transistors 102 and 110 off) and the control signals S1 and S3 asserted (to switch transistors 108 and 112 on).

However, a finite time may elapse between these two events due to the speed of the programming circuitry of the programmable logic device. During the finite time, for example, that the control signals S0 and S2 are deasserted and the control signals S1 and S3 are not yet asserted, multiplexer 100 is not allowing through any of the input signals. Thus, multiplexer 100 is under the control of transistor 120, which will only pull-up a voltage level at node 118 to the supply voltage (VCC) if the initial voltage at node 118 is high enough (i.e., reaches the trip point of inverter 122) to force inverter 122 to provide a logical low output signal.

In general, transistor 120 functions as a level restorer to pull-up the voltage level of node 118 to the supply voltage, because transistors 102 through 112 (e.g., N channel metal oxide semiconductor (NMOS) transistors) cannot pass the full supply voltage level provided by one of the input signals (one of IN1 through IN4) to node 118. If the initial voltage at node 118 is not high enough for this example during the finite time, the voltage level at node 118 can float between a ground voltage level and the trip point of inverter 122, which may result in crowbar current through inverter 122.

In general, during reconfiguration of a programmable logic device, all of the input paths may be temporarily switched off (based on the above example) while for example the configuration memory for that multiplexer is being reprogrammed (e.g., when switching the desired input path from one input path to another). This may temporarily tri-state node 118 of multiplexer 100, resulting in potential power spikes through inverters 122 and 124 of multiplexer 100. This power spike threat may limit the number of multiplexers (e.g., associated with various blocks of logic within the programmable logic device) that can be reprogrammed at or near the same time.

In contrast, in accordance with an embodiment of the present invention, multiplexer 200 includes a full-latch (i.e., transistors 120 and 204). Consequently, when transistors 102 through 112 are switched off and node 118 is not provided with any of the input signals (IN1 through IN4), such as during reconfiguration for example, the full-latch will pull the voltage level at node 118 to either ground or supply voltage level, depending on its previous state. Therefore, the crowbar current through inverters 122 and 124 will be eliminated.

In accordance with one or more embodiments of the present invention, systems and methods are provided for multiplexer circuits that do not require the use of one of their multiplexer input paths as a default-state input path, removes the requirement for software tie-downs, may decrease software complexity, and may increase routing resources. The pseudo-loading effect in unused multiplexers may be eliminated, which greatly reduces leakage currents and reduces propagation delays. Furthermore, the possibility of internal node 188 floating during reconfiguration is removed.

For example, in accordance with one embodiment of the present invention, a multiplexer is disclosed that includes a full latch (e.g., a state-locking latch to conserve power) and/or a default-state pull-down (or pull-up) transistor, which may be incorporated into a programmable logic device or other types of circuits requiring multiplexers. The default-state pull-down (or pull-up) transistor frees the multiplexer from requiring a dedicated default-state input path. For example, instead of employing an input path to pull the internal multiplexer node to a rail, all of the multiplexer input paths are switched off and the pull-down or pull-up transistor pulls the node to a rail. This also frees up the otherwise dedicated default-state path to be used as a normal signal route. Software also no longer needs to find a default-state path, which may reduce the software's complexity.

Furthermore, by defaulting each unused multiplexer in the routing to one rail by using its pull-down or pull-up device and signal throughout (e.g., a global signal within the integrated circuit), DC leakage may be significantly reduced. The default state of each multiplexer is no longer determined by unused signals. As an example, if a majority of the multiplexers within the integrated circuit are unused, the majority of the signals to any multiplexer will now be at the same potential and, therefore, only the few active signals will create leakage paths (e.g., as opposed to a random distribution of logical high and low signal levels for unused multiplexers in conventional circuits).

In the unused multiplexers, the existence of the default-state pull-down (or pull-up) and the full-latch device permits all of the input signal multiplexer pass gates (e.g., transistors 102 through 112) to be switched off. Therefore, the extra capacitance and leakage paths associated with the pseudo-loading effect may be eliminated from unused multiplexers, resulting in less DC leakage current, smaller propagation delays, and potentially less AC current.

Furthermore, the full latch functions as a “state-locker” for the multiplexer during reconfiguration. In the event that all of the input signals for the multiplexer are temporarily blocked (e.g., when a different input path is being selected in an already used multiplexer), the full latch will hold the internal multiplexer node (e.g., node 118) at its last state value, which prevents a power spike through the driver inverters.

Embodiments described above illustrate but do not limit the invention. It should also be understood that numerous modifications and variations are possible in accordance with the principles of the present invention. Accordingly, the scope of the invention is defined only by the following claims.

1. A multiplexer comprising:
a plurality of first transistors adapted to receive a plurality of input signals, wherein the plurality of first transistors provides at least two first-stage multiplexer output signals;
a plurality of second transistors adapted to receive the first-stage multiplexer output signals and provide a second-stage multiplexer output signal;
a first inverter adapted to receive the second-stage multiplexer output signal at an input terminal and provide an output signal at an output terminal;
a third transistor, coupled to the input terminal of the first inverter, adapted to pull a voltage level at the input terminal to a rail voltage; and
a fourth transistor, coupled to the input terminal and the output terminal of the first inverter.

2. The multiplexer of claim 1, wherein the fourth transistor is adapted to maintain a voltage level at the input terminal of the first inverter at a rail voltage based upon a voltage level of the output signal at the output terminal of the first inverter.

3. The multiplexer of claim 1, wherein the third transistor is adapted to receive a control signal, the third transistor pulling the voltage level at the input terminal to a rail voltage when the control signal is asserted.

4. The multiplexer of claim 3, wherein the rail voltage is a ground voltage level or a supply voltage level.

5. The multiplexer of claim 1, further comprising a fifth transistor, coupled to the input terminal and the output terminal of the first inverter.

6. The multiplexer of claim 5, wherein the fourth and fifth transistor and the first inverter form a full latch, the fourth and fifth transistor maintaining the voltage level at the input terminal to approximately a supply voltage level and a ground voltage level, respectively, depending upon the output signal at the output terminal of the first inverter.

7. The multiplexer of claim 1, wherein the first and second transistors are adapted to receive control signals which determine the input signal to provide as the second-stage multiplexer output signal.

8. The multiplexer of claim 1, further comprising a second inverter, coupled to the first inverter, adapted to receive the output signal and provide a final output signal for the multiplexer.

9. The multiplexer of claim 1, wherein the multiplexer is one of a plurality of multiplexers within an integrated circuit.

10. The multiplexer of claim 9, wherein the integrated circuit comprises a field programmable gate array, a complex programmable logic device, or a programmable interconnect device.

11. A programmable logic device having a plurality of multiplexers, with each multiplexer of the plurality comprising:
a plurality of first transistors adapted to receive input signals and provide a multiplexed output signal;
a first inverter having an input terminal and an output terminal, the first inverter adapted to receive the multiplexed output signal at the input terminal and provide an inverted output signal at the output terminal;
a second and a third transistor coupled to the input terminal and the output terminal of the first inverter, which form a full latch; and
a fourth transistor, coupled to the input terminal of the first inverter, adapted to receive a control signal and pull a voltage level at the input terminal to a rail voltage when the control signal is asserted.

12. The programmable logic device of claim 11, wherein the control signal is a global signal.

13. The programmable logic device of claim 11, wherein the first transistors form a plurality of first stages and at least a second stage.

14. The programmable logic device of claim 11, further comprising a second inverter adapted to receive the inverted output signal and provide a multiplexer output signal for the multiplexer.

15. A method of operating a multiplexer within a programmable logic device, the method comprising:
providing a first control signal to the multiplexer to set an output signal of the multiplexer to a default state;
maintaining the default state of the output signal of the multiplexer; and
providing at least a second control signal to determine which if any of a plurality of input signals to select and provide as the output signal of the multiplexer.

16. The method of claim 15, wherein the programmable logic device comprises a plurality of the multiplexers and the first control signal is a global signal to the multiplexers.

17. The method of claim 15, wherein the default state of the output signal is a logical high or a logical low signal level.

18. The method of claim 15, wherein the at least second control signal controls a plurality of transistors which form multiple multiplexer stages adapted to receive and select from among the plurality of input signals.

19. The method of claim 15, wherein the maintaining is performed by a full latch.

20. The method of claim 15, wherein the programmable logic device comprises a field programmable gate array, a complex programmable logic device, or a programmable interconnect device.

21. A multiplexer comprising:
a plurality of first transistors adapted to receive a plurality of input signals, wherein the plurality of first transistors provides a multiplexer output signal;
an inverter adapted to receive the multiplexer output signal at an input terminal and provide an output signal at an output terminal;
a second transistor, coupled to the input terminal of the. inverter, adapted to pull a voltage level at the input terminal to a rail voltage; and
a third transistor, coupled to the input terminal and the output terminal of the inverter, adapted to maintain a voltage level at the input terminal at the rail voltage based upon a voltage level of the output signal at the output terminal.

22. The multiplexer of claim 21, further comprising a fourth transistor, coupled to the input terminal and the output terminal of the inverter, wherein the inverter, the third transistor, and the fourth transistor form a full latch.

23. The multiplexer of claim 21, wherein the second transistor is further adapted to receive a control signal, the second transistor pulling a voltage level at the input terminal to the rail voltage when the control signal is asserted.

24. The multiplexer of claim 21, wherein the second transistor forms a pull-up or a pull-down transistor.
